(19) United States
(12) Patent Application Publication
(10) Pub. No.: US 2026/0020193 A1
(43) Pub. Date: Jan. 15, 2026

(54) UNINTERRUPTIBLE COOLING SUPPLY

(71) Applicant: CGG Services SAS, Massy Cedex (FR)

(72) Inventor: Laurent Clerc, Houston, TX (US)

(73) Assignee: CGG Services SAS, Massy Cedex (FR)

(21) Appl. No.: 18/772,742

(22) Filed: Jul. 15, 2024

(51) Int. Cl. H05K 7/20

(52) U.S. Cl. CPC H05K 7/20463; H05K 7/202; H05K 7/20263; H05K 7/20427

(57) ABSTRACT

An uninterruptible cooling system includes a heat generating electronic component enshrouded by a first container, a heat exchanger enshrouded by a second container, and an Uninterruptible Cooling Supply (UCS). The uninterruptible cooling system further includes a heat exchange fluid and a fluid pump to circulate the heat exchange fluid through conduits fluidly connecting the first container, the second container, and the UCS. The UCS includes a radiator enshrouded by a casing and a heat transfer compound positioned in a space external to the radiator and internal to the casing. The heat transfer compound within the Uninterruptible Cooling Supply has a solid to liquid phase change threshold that is greater than the operating temperature of the heat exchange fluid downstream of the heat exchanger and less than the maximum temperature of the heat generating electronic component.

### BACKGROUND

Electronic systems generate heat during operation requiring removal to ensure that an adequate temperature range is maintained for the system. In conventional systems, heat is removed by running a fluid through the system to either exchange heat with another fluid externally, via an external cooling system, or to dissipate heat to the environment. In these systems, if the external cooling system fails the electronic system may overheat quickly, resulting in potential system failures and damaged equipment. Accordingly, it is desirable to absorb heat from the system in the case of an external cooling system failure.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

Embodiments disclosed herein relate to an uninterruptible cooling system containing a heat generating electronic component enshrouded by a first container, a heat exchanger enshrouded by a second container, and an Uninterruptible Cooling Supply (UCS). The uninterruptible cooling system contains a heat exchange fluid and a fluid pump to circulate the heat exchange fluid through conduits fluidly connecting the first container, the second container, and the UCS. The UCS contains a radiator enshrouded by a casing and a heat transfer compound disposed in a space external to the radiator and internal to the casing. The heat transfer compound within the Uninterruptible Cooling Supply has a solid to liquid phase change threshold that is greater than the operating temperature of the heat exchange fluid downstream of the heat exchanger and less than the maximum temperature of the heat generating electronic component.

Embodiments disclosed herein further relate to a method for removing heat from a heat exchange fluid using a heat transfer compound by circulating the heat exchange fluid through the first container containing the heat generating electronic component to the second container containing the heat exchanger. The heat transferred by the heat generating electronic component to the heat exchange fluid is absorbed by the heat exchanger. The heat exchange fluid is circulated from the second container to an Uninterruptible Cooling Supply. Heat is rejected from the heat exchange compound into the heat exchange fluid until the heat exchange compound in the Uninterruptible Cooling Supply reaches a solid state when the operating temperature of the heat exchange fluid downstream of the heat exchanger is at or below the phase change threshold. The heat transfer compound absorbs heat from the heat exchange fluid when the operating temperature of the heat exchange fluid is above the phase change threshold.

Any combinations of the various embodiments and implementations disclosed herein can be used in a further embodiment, consistent with the disclosure. Other aspects and advantages of the claimed subject matter will be apparent from the following description and the claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility.

FIG. 1 depicts an uninterruptible cooling supply in an electronic system in accordance with one or more embodiments.

FIG. 2A-2C depict an uninterruptible cooling supply in accordance with one or more embodiments.

FIG. 3 depicts an uninterruptible cooling supply with a casing containing a liner in accordance with one or more embodiments.

FIG. 4 depicts an uninterruptible cooling supply with collapsible sections of the casing in accordance with one or more embodiments.

FIG. 5 depicts the method for operating an uninterruptible cooling supply using a heat transfer compound in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not intended to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements. Furthermore, while certain components are referred to in the singular to simplify discussion of embodiments of the invention, those skilled in the art will appreciate that any individual component (i.e., an electronic component) may be replaced with a multitude of components in advanced embodiments of the invention.

In general, embodiments of the invention are directed towards an uninterruptible cooling system. The uninterruptible cooling system includes an electronic system contained within a first container and cooling equipment contained within a second container. The uninterruptible cooling system includes a fluid circulating through the first container to the second container through a sealed fluid circuit. The uninterruptible cooling system further includes a receptacle, referred to as an Uninterruptible Cooling Supply (UCS), within the uninterruptible cooling system that includes a heat exchange structure within a casing that contains a chemical compound.

Embodiments of the invention are further directed towards a method for removing heat from a fluid using a heat transfer compound by circulating the fluid through an electronic system, cooling equipment, and an Uninterruptible Cooling Supply (UCS). Embodiments of the invention are directed towards a method for removing heat from a fluid using a chemical compound when the cooling equipment is in a failure mode.

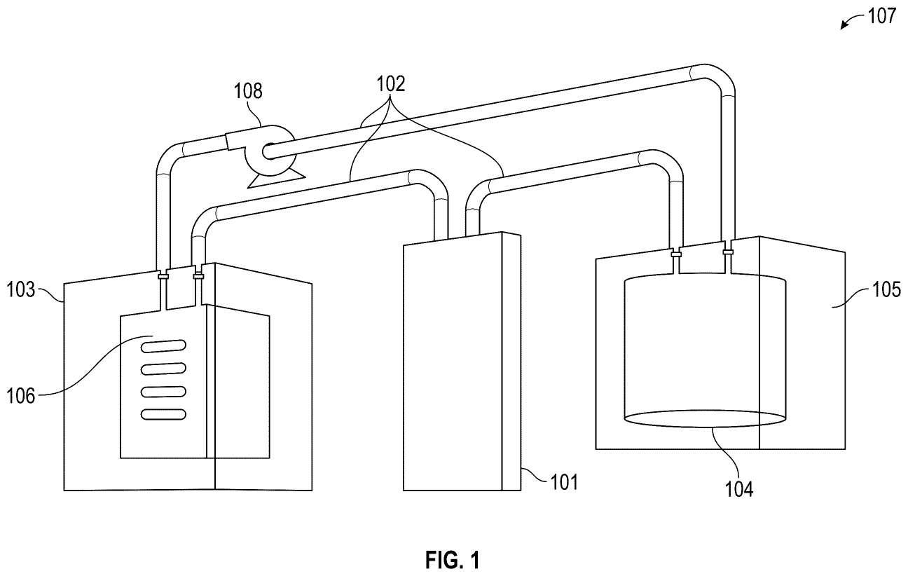

FIG. 1 depicts an Uninterruptible Cooling Supply (UCS) 101 in an electronic system 107 in accordance with one or more embodiments disclosed herein. FIG. 1 shows that the electronic system 107 includes a first container 105 enshrouding a heat generating electronic component 104 and a second container 103 that enshrouds a heat exchanger 106 such as a radiator. A plurality of conduits 102 connect the UCS 101 to both the first container 105 and the second container 103. The plurality of conduits 102 also connects the first container 105 directly to the second container 103. The conduits 102 may be made of metal or rubber tubes, depending on the heat exchange fluid.

The heat generating electronic component 104 requires heat removal throughout operation to maintain a consistent temperature within a manufacturer's suggested operating range. For example, maintaining a consistent temperature may be within approximately 20% of a target temperature value, as some variation is expected. Exceeding the manufacturer's suggested operating range may result in failures of the heat generating electronic component 104 including equipment damage. In one or more embodiments, this temperature is, at a minimum, less than the melting point of solder, which is approximately 90 to 450° C. (190 to 840° F.) depending on the composition thereof. The maximum temperature of a particular electronic component 104 may also vary significantly between components based upon the type of component being used and is typically defined by the manufacturer of the heat generating electronic component 104. Moreover, exceeding the manufacturer's suggested operating range may result in throttling of the heat generating electronic component 104 to reduce heat output such that performance may be impacted.

The heat generating electronic component 104 may be configured to execute computer readable instructions. In one or more embodiments, the heat generating electronic component 104 may be embodied as a server such as a blade server or a rack server. Alternatively, the heat generating electronic component 104 may be embodied as including one or more computing hardware devices such as a microprocessor, a processing unit such as a Central Processing Unit (CPU) and/or a Graphics Processing Unit (GPU), a storage medium (e.g., a Hard Disk Drive (HDD), a Solid State Drive (SDD), or Random Access Memory (RAM)), and/or a communication device (e.g., ethernet, Wi-Fi, or other Local Area Network (LAN) or Wide Area Network (WAN) interconnects) such as a transceiver or networking card that serves to transmit and receive signals. However, the above description of the heat generating electronic component 104 is not intended to limit the type of component, and, thus, the heat generating electronic component 104 as described herein may further encompass various other electrically powered devices, equipment, and/or hardware known to a person having ordinary skill in the art.

In the Uninterruptible Cooling System, the heat generating electronic component 104 is enshrouded within a first container 105 that receives a heat exchange fluid, absorbing heat from the heat generating electronic component 104. The heat exchange fluid may be water, gas, mineral oil, or any other fluid suitable for absorbing heat from the heat generating electronic component 104.

The heat exchanger 106 is configured to receive and transfer heat away from the heat exchange fluid that has absorbed heat by circulating through the first container 105 containing the heat generating electronic component 104. When the heat exchanger 106 is operating normally, the heat exchanger 106 reduces the temperature of the heat exchange fluid. Specifically, the heat exchange fluid flowing upstream of the heat exchanger 106 is heated by the heat generating electronic component 104 to a temperature greater than the phase change threshold of the heat transfer compound. The heat exchanger 106 reduces the temperature of the heat exchange fluid to a temperature less than or equal to the phase change threshold. Thus, the heat exchange fluid flowing downstream of the heat exchanger 106 towards the UCS 101 has a temperature less than the phase change threshold during normal operating conditions. The heat exchange fluid is circulated through the plurality of conduits in the system using a fluid pump 108, which may be located between the first container 105 and the second container 103, or disposed directly in the first container 105 or the second container 103, such that the temperature of the heat exchange fluid is maintained throughout the system operation. In one or more embodiments, the fluid pump may be a centrifugal pump. In other embodiments, the fluid pump may be a positive displacement pump.

In one or more embodiments, the heat exchanger 106 is the primary cooling mechanism for cooling the heat generating electronic component 104 during normal operations by rejecting heat to an air stream flowing through the heat exchanger 106. In this regard, the heat exchanger 106 may be embodied as a radiator such as a shell and tube radiator, a plate style heat exchanger, a fin heat exchanger, or equivalent device. In one or more embodiments, the heat exchanger 106 may be integrated with a liquid cooling environment. For example, the heat exchanger 106 may be integrated with a chilled water cooling loop embodied in a datacenter.

During normal operation of the heat exchanger 106, as the heat exchange fluid is cooled to an operating temperature less than the phase change threshold of the heat transfer compound by the heat exchanger 106, the heat transfer compound will remain in a solid state in the UCS 101, and thus will not be absorbing heat from the heat exchange fluid. In these embodiments, if the heat transfer compound is initially at a temperature greater than the temperature of the heat exchange fluid, the heat transfer compound may reject heat to the heat exchange fluid, resulting in further solidification of the heat transfer compound. However, when the heat exchanger 106 is in a failure mode, the UCS 101 serves as a secondary cooling mechanism for the heat exchange fluid to protect the heat generating electronic component 104. An example of a failure mode may include equipment damage to the second container 103 or the heat exchanger 106, or, more generally, any situation that causes the second container to be unable to adequately reduce the temperature of the heat exchange fluid.

Overall, if the temperature of the heat exchange fluid downstream of the heat exchanger 106 exceeds the phase change threshold of the heat transfer compound, the heat transfer compound will transition to liquid. As long as a portion of solid heat transfer compound remains (i.e., the heat transfer compound is not in a fully liquid state), the heat transfer compound will absorb heat from the cooling fluid at constant temperature. When the temperature of the heat exchange fluid drops below the phase change threshold, the heat transfer compound will shed heat until it is solid again, regenerating the capacity to absorb heat with the UCS 101 if the heat exchange fluid temperature subsequently drops below the phase change threshold. During this period of time, heat is rejected from the heat transfer compound into the heat exchange fluid until the heat transfer compound in the UCS 101 reaches a solid state and the operating temperature of the heat exchange fluid downstream of the heat exchanger 106 is at or below the phase change threshold.

As discussed above, the first container 105 enshrouds the heat generating electronic component 104 and the second container 103 enshrouds the heat exchanger 106. The first container 105 and second container 103 may be cylindrical containers (not shown) configured with an open top, and may be formed of a metal such as a chrome-molybdenum steel alloy, a vanadium steel alloy, a nickel steel alloy, or an equivalent metal. Alternatively, the cylindrical container may be formed of a plastic polymer such as polyvinyl chloride (PVC), high-density polyethylene (HDPE), nylon, or polystyrene, for example, and may take the form of a cube, rectangular prism, or other polyhedrons without departing from the nature of this disclosure.

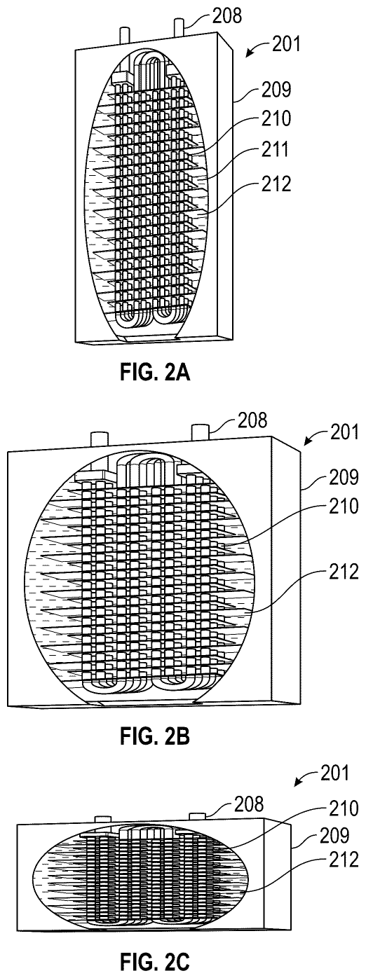

FIG. 2A-2C depict an Uninterruptible Cooling Supply (UCS) 201 in accordance with one or more embodiments disclosed herein. The UCS 201 may be a variety of different sizes and geometries. For example, in one or more embodiments, the UCS 201 may be a rectangular prism with a longer vertical dimension than horizontal dimension, as is illustrated in FIG. 2A. In one or more embodiments, the UCS 201 may be a square prism as is illustrated in FIG. 2B. As illustrated in FIG. 2C, the UCS 201 may be a rectangular prism with a longer horizontal dimension than vertical dimension. In the spirit of FIG. 2A-2C, the UCS 201 may take other polyhedral shapes such as a trapezoidal prism with an elongated base. The shape and size of the UCS 201 may be selected based on spatial constraints or the heat load of the heat generating electronic component 104.

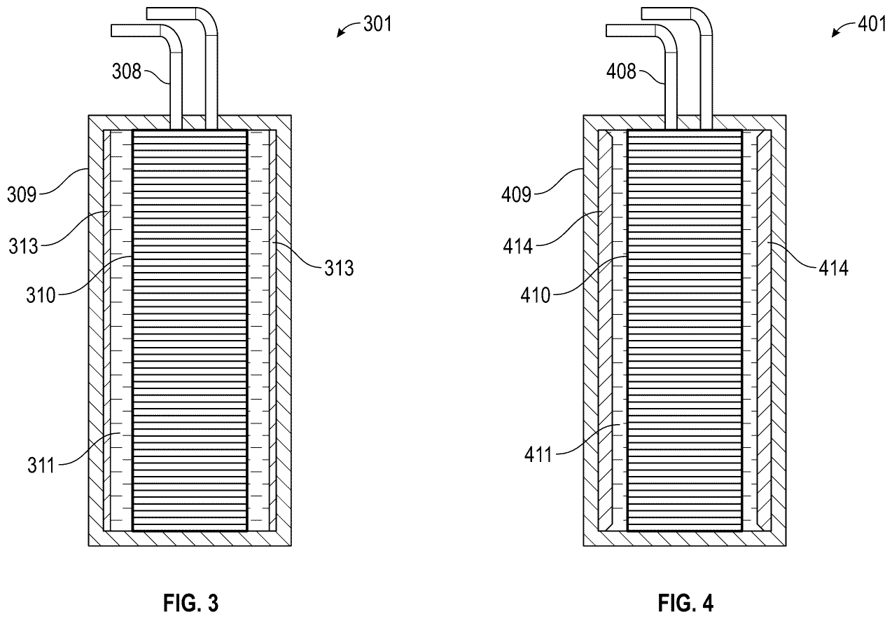

Components of FIG. 2A-2C sharing a same or similar name to components in FIG. 1 are generally imbued with the same or substantially similar properties or features unless discussed otherwise, but may naturally encompass or require additional functionality, structures, and/or materials not discussed above. In addition, similar components are denoted with similar component numberings. For example, FIG. 1 depicts an Uninterruptible Cooling Supply 101, which is similar or the same as the Uninterruptible Cooling Supply 201 of FIG. 2A-2C, as denoted by the final two numbers of both components being “01.” Although not discussed further below for the sake of brevity, components of FIG. 3-5 are numbered in a similar manner.

As shown in FIG. 2A-2C, a casing 209 enshrouds the radiator 210, and the heat transfer compound 211 is disposed in a space external to the radiator 210 and internal to the casing 209. The heat transfer compound within the UCS is selected so that the temperature at which solid to liquid phase change occurs is: (1) higher than the normal operating temperature of the heat exchange fluid at the outlet of the heat exchanger, and (2) sufficiently low such that when the heat exchanger fails, the operating temperature of the heat generating electronic component 104 is maintained below a maximum threshold therefor. The heat transfer compound 211 exchanges heat with the heat exchange fluid, which flows through the fluid circuit 208, either absorbing or rejecting heat to the heat exchange fluid as it flows through the radiator 210, depending on the temperature differential between the heat transfer compound 211 and the heat exchange fluid. For example, when the temperature of the heat transfer compound 211 is greater than the temperature of the heat exchange fluid, the heat transfer compound 211 rejects heat to the heat exchange fluid, thereby warming the heat exchange fluid. When the temperature of the heat transfer compound 211 is less than that of the heat exchange fluid, the heat transfer compound 211 absorbs heat from the heat exchange fluid, cooling the heat exchange fluid. During the phase change of the heat transfer compound, the temperature of the heat exchange fluid is maintained at a constant temperature for the period of time that encompasses the phase change.

Thus, overall, the phase change compound is selected such that heat exchange fluid that has passed through the UCS 201 has a reduced or maintained temperature that is less than the maximum operating temperature of the electronic component. It is noted that there is thermal resistance between the electronic component 104 and the heat exchange fluid due to numerous physical characteristics such as the surface tension of the heat exchange fluid and the casing of the electronic component 104 retaining residual heat. While the heat exchange fluid is thus described as being retained at a temperature less than the maximum operating temperature of the heat generating electronic component, such may also necessarily encompass modifying the maximum temperature of the heat exchange fluid to account for the thermal resistance. That is, the maximum temperature of the heat exchange fluid may be constrained to a temperature that is a percentage (e.g., 95-99%) of the maximum operating temperature of the electronic component, rather than being explicitly equivalent to the maximum operating temperature. Along the same lines, when the heat transfer compound is not in a transition phase, and is either fully solid or fully liquid, the heat transfer compound will still provide a thermal dampening effect that delays temperature changes of the electronic component 104 and heat exchange fluid.

The above-described operating conditions result in phase changes of the heat transfer compound 211 depending on the final temperature of the heat transfer compound 211 following the heat exchange. If the temperature of the heat transfer compound 211 is greater than the phase change threshold, the heat transfer compound 211 will transition to, or be in, a liquid phase. If the temperature of the heat transfer compound 211 is less than the phase change threshold, the heat transfer compound 211 will be in a solid phase. The heat transfer compound 211 may contain paraffin wax or glycerin. The heat transfer compound 211 may be selected to correspond to the typical operating temperature of the heat exchange fluid in the system. The specific phase change threshold will vary depending on the specific composition of the heat transfer compound 211 used. For example, waste paraffin wax has a melting point of 102° C. (i.e., a phase change threshold of 102° C.), L-PW wax has a melting point of 18° C. (i.e., a phase change threshold of 18° C.), and scale wax has a melting point of 52° C. (i.e., a phase change threshold of 52° C.). Thus, the specific value of the phase change threshold varies according to the exact composition of the heat transfer compound.

In general, the heat transfer compound within the UCS is selected so that the temperature at which solid to liquid phase change occurs is: (1) higher than the normal operating temperature of the heat exchange fluid at the outlet of the heat exchanger, and (2) sufficiently low such that when the heat exchanger fails, the operating temperature of the heat generating electronic component 104 is maintained below a maximum threshold therefor. Along the same lines, the phase change threshold will typically fall within a range of 18 to 102° C., inclusive. In conjunction with the above descriptions regarding the heat load emitted by the electronic component 104, the phase change threshold is selected by an operator or engineer of the system based upon the contemplated heat load produced by the electronic component 104 when the radiator 210 has failed. When the heat transfer compound is glycerin, the phase change threshold temperature is approximately 17° C. The paraffin wax may be suitable for embodiments where the typical operating temperature of the heat exchange fluid is above 17° C., while the glycerin may be suitable for embodiments where the typical operating temperature of the heat exchange fluid is at or below 17° C. During the time period encompassing the phase change, the temperature of the heat exchange fluid remains constant.

The casing 209 is configured to fully contain the heat transfer compound 211 in both the solid and liquid phases, regardless of which phase the heat transfer compound 211 is in. When the heat exchanger 106 in the second container 103 is operational, the heat exchange fluid circulating through the system is typically cooler than the heat transfer compound 211, and the heat transfer compound 211 rejects heat to the heat exchange fluid, further solidifying within the casing 209 as the heat exchange fluid flows through the radiator 210. When the heat exchanger 106 in the second container 103 is in a failure mode, the heat exchange fluid circulating through the system 107 is no longer cooled by the heat exchanger 106 and thus the temperature of the heat exchange fluid is typically higher than that of the heat transfer compound. In this case, the temperature of the heat exchange fluid increases to an elevated operating temperature that is greater than the phase change threshold for the heat transfer compound and less than the maximum temperature of the heat generating electronic component. As a result, the heat transfer compound 211 around the radiator 210 changes to a liquid phase, absorbing the heat from the heat exchange fluid, resulting in a cooled heat exchange fluid flowing back to the heat generating electronic component.

The heat exchange compound 211 will continue to absorb heat until it has entirely changed from a solid state to a liquid state. In the event that the heat exchanger 106 has failed and the heat transfer compound 211 has exhausted its ability to retain heat (i.e., the heat transfer compound 211 is fully liquid), the temperature of the electronic component 104 may rise above the maximum operating temperature therefor. As a result, the UCS 201 offers a window of time when the heat exchanger 106 may be repaired, or the system may be disabled in the event that the heat exchanger 106 needs to be replaced or extensive repairs are warranted. The duration of time where the UCS 201 is operable to receive heat from the heat exchange fluid depends on the size of the UCS 201 and the volume of heat transfer compound 211 contained therein.

The casing 209 and radiator 210 of the UCS 201 may contain a variety of different geometries and features to facilitate effective heat transfer from the heat exchange fluid to the heat transfer compound 211. In general, the size of the radiator 210 and the size of the UCS 201 are selected by an operator or system engineer to correspond to a measured or contemplated heat load of the heat generating electronic component. The radiator 210 may be a tube and fin type heat exchanger, a plate and fin type heat exchanger, or a different heat exchanger type designed to maximize the area of contact with the heat exchange fluid. The radiator 210 includes a series of baffles 212 that provide a flat surface that abuts against a portion of the heat transfer compound 211 for conductive heat transfer. In one or more embodiments, the baffles 212 are arranged in a staggered configuration and are oriented perpendicularly to the flow path of the heat exchange fluid through the radiator 210. The staggered configuration evenly distributes heat throughout the UCS 201 by allowing some of the baffles 212 to transfer heat from the heat exchange fluid to the heat transfer compound 211 disposed on the inlet side of the UCS 201, and allowing the remaining baffles 212 to transfer heat from the heat exchange fluid to the heat transfer compound 211 disposed on the outlet side of the UCS 201.

The UCS 201 may be a rectangular prism or a square prism with horizontal and vertical dimensions that correspond to a particular cooling environment. In one or more embodiments, the UCS 201 may be formed in the shape of a rectangular prism with a longer vertical dimension than horizontal dimension. In other embodiments, the UCS 201 may be formed in the shape of a rectangular prism with a longer horizontal dimension than vertical dimension. In other embodiments, the UCS 201 may be formed in the shape of a cylinder, an elliptical cylinder, or a polyhedron. The casing 209 may include a liner (e.g., FIG. 3) which deforms with the heat transfer compound 211 during phase changes to ensure that the heat transfer compound 211 remains in continuous contact with the radiator 210 despite contraction and expansion of the heat transfer compound 211 as it transitions between states. Alternatively, the casing 209 may include compressible sections (e.g., FIG. 4) allowing for flexible deformation of the casing 209 during phase change to prevent any equipment damage. As will be appreciated by a person having ordinary skill in the art, the casing 209 may include small collapsible elastic balls, a bladder, a balloon, or any suitable heat transfer compound 211 retention mechanism in place of a liner. Any combination of these features, geometries, and sizes may be utilized in the configuration of the UCS 201 based on spatial constraints and the heat load of the heat generating electronic component (104).

FIG. 3 depicts an uninterruptible cooling supply 301 with a casing 309 containing a liner in accordance with one or more embodiments disclosed herein. As shown in FIG. 3, a casing 309 enshrouds a radiator 310. The radiator 310 is connected to the first container 105 and the second container 103 via the fluid circuit 308. There is a liner 313 within the casing 309, which deforms with the heat transfer compound 311 during phase changes to retain the heat transfer compound 311 against the baffles 212 despite expansion of the heat transfer compound 311 as it transitions states. The liner 313 may be made of a flexible material attached to the radiator 310, such that the liner 313 forms a flexible bag around the radiator 310. The liner may be made of a polymer material that deforms based on the phase of the heat transfer compound 311. For example, when the heat transfer compound 311 is in a solid phase, the liner 313 may elastically deform to accommodate the spatial requirements of the solid phase, and when the heat transfer compound 311 is in a liquid phase, the liner 313 may retract to an original shape.

FIG. 4 depicts an uninterruptible cooling supply 401 with compressible sections 414 of the casing in accordance with one or more embodiments disclosed herein. As shown in FIG. 4, a casing 409 enshrouds a radiator 410. The radiator 410 is connected to the first container 105 and the second container 103 via the fluid circuit 408. The casing 409 includes compressible sections 414, which allow for flexible deformation of the casing 409 when the heat transfer compound 411 deforms during phase changes, retaining the heat transfer compound 411 against the baffles 212. The compressible sections 414 may be made of a polymer material that compresses the heat transfer compound between the casing 409 and the radiator 410.

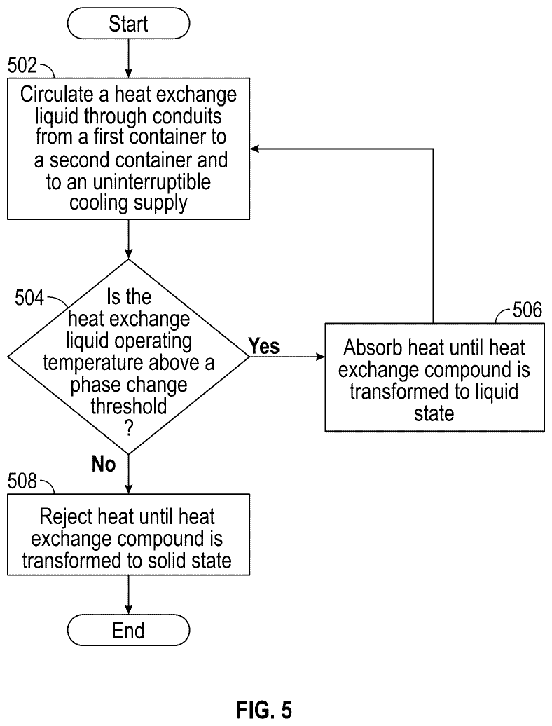

As illustrated in FIG. 5, the method for operating an uninterruptible cooling supply using a heat transfer compound initiates in step 502. Specifically, step 502 includes circulating the heat exchange fluid through conduits from the first container containing the heat generating electronic component, to the second container containing the heat exchanger, to the uninterruptible cooling supply, and back to the first container. In one or more embodiments, the order of the flow between elements may vary so long as the circulation essentially forms a closed-loop system.

In one or more embodiments, the heat exchange fluid is circulated by way of a pump or convective currents. In other words, the circulation in step 502 may be continuous such that in normal operation the heat generating electronic component is continuously cooled by rejecting heat into the heat exchange fluid that is continuously circulating.

In step 504, a determination is made as to whether the temperature of the heat exchange liquid is above a phase change threshold. In one or more embodiments, the determination may be passive (i.e., the heat transfer compound may simply begin changing phase). Additionally, or alternatively, the uninterruptible cooling supply may receive an alert that the heat exchanger has failed. Put differently, the temperature of the exceeding a phase change threshold may indicate a failure of the heat exchanger. Further, the temperature of the heat exchange liquid returning to or falling below the phase change threshold may indicate that the operation of the heat exchanger has resumed (e.g., the heat exchanger has been replaced or repaired). If the determination is made that the temperature of the heat exchange liquid is above the phase change threshold, the method moves to step 506. If the temperature of the heat exchange fluid is at or below the phase change threshold, then the method moves to step 508.

In step 506, the uninterruptible cooling supply absorbs heat from the heat exchange liquid until the heat transfer compound is transformed to a liquid state. In other words, the heat transfer compound may begin changing phase to absorb heat from the heat exchange liquid. Step 506 may, for example, be performed continuously such that heat is absorbed from the heat exchange liquid until the cooling capacity of the heat transfer compound is exhausted (i.e., the heat transfer compound has fully changed state). In one or more embodiments, the method returns to step 502 such that the heat exchange fluid continues to circulate through the system to cool the heat generating electronic component.

In step 508, the uninterruptible cooling supply rejects heat into the heat exchange liquid until the heat transfer compound is transformed to a solid state. In other words, the heat transfer compound may reject heat into the heat exchange fluid until it has reached a steady state or pseudo steady state condition after the phase change. In one or more embodiments, the heat transfer compound may already be fully in the solid state (i.e., there is no heat to reject at the outset of step 508). In one or more embodiments, once the heat transfer compound reaches a terminal state, the method ends as the system returns to normal operation where the uninterruptible cooling supply is in a steady state and the heat generating electronic component is cooled by the circulated heat exchange fluid and heat exchanger. Alternatively, the method may return to step 502.

Although only a few example embodiments have been described in detail above, those skilled in the art will readily appreciate that many modifications are possible in the example embodiments without materially departing from this invention. For example, although the disclosure describes the use of a single radiator connected to a conduit, additional radiators (each connected to an additional conduit) may be positioned within the system to increase the cooling capacity. In addition, many modifications will be appreciated by those skilled in the art to adapt a particular instrument, situation, or material to embodiments of the disclosure without departing from the essential scope thereof. Thus, all such modifications are intended to be included within the scope of this disclosure.

Embodiments of the present disclosure may provide at least one of the following advantages. By providing the heat generating electronic component with a backup, uninterruptible cooling supply, it ensures that general system failures to the heat exchanger will not result in overheating and equipment damage for the heat generating electronic component if corrected before the cooling capacity of the heat transfer compound is exhausted. By using a heat transfer compound with a phase change threshold at a temperature slightly greater than the operating temperature of the heat exchange fluid, this ensures that the UCS is functional quickly upon failure of the heat exchanger. The simple and passive yet effective design of the Uninterruptible Cooling Supply (UCS) ensures reliable, quick, and temporary cooling for the heat exchange fluid throughout operation without a need for a backup power supply or complex, costly engineering redundancies to manage failures.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. An uninterruptible cooling system comprising:
a heat generating electronic component, configured to execute computer readable instructions;
a first container configured to enshroud the heat generating electronic component;
a heat exchange fluid, circulating through the first container, that is configured to absorb heat from the heat generating electronic component;
a heat exchanger configured to receive and transfer heat away from the heat exchange fluid;
a second container configured to enshroud the heat exchanger;
an Uninterruptible Cooling Supply (UCS) comprising:
a radiator configured to exchange heat with the heat exchange fluid;
a casing configured to enshroud the radiator, and
a heat transfer compound disposed in a space external to the radiator and internal to the casing,
wherein the heat transfer compound comprises a substance with a solid to liquid phase change threshold that is greater than an operating temperature of the heat exchange fluid downstream of the heat exchanger and less than a maximum temperature of the heat generating electronic component,
a plurality of conduits configured to fluidly connect the first container, the second container, and the UCS; and
a fluid pump configured to pump the heat exchange fluid through the plurality of conduits.

2. The uninterruptible cooling system of claim 1, wherein the radiator comprises a series of baffles.

3. The uninterruptible cooling system of claim 1, wherein the casing further comprises a liner.

4. The uninterruptible cooling system of claim 1, wherein the casing further comprises a plurality of compressible sections.

5. The uninterruptible cooling system of claim 2, wherein the series of baffles is arranged in a staggered configuration.

6. The uninterruptible cooling system of claim 2, wherein each baffle includes a flat surface that abuts against a portion of the heat transfer compound.

7. The uninterruptible cooling system of claim 2, wherein the series of baffles is oriented perpendicularly to a flow path of the heat exchange fluid in the radiator.

8. The uninterruptible cooling system of claim 1, wherein the casing is configured to fully contain the heat transfer compound regardless of whether the heat transfer compound is in a solid phase or a liquid phase.

9. The uninterruptible cooling system of claim 1, wherein a radiator size and a casing size are selected to correspond to a heat load of the heat generating electronic component.

10. The uninterruptible cooling system of claim 1, wherein the heat transfer compound comprises paraffin wax or glycerin.

11. The uninterruptible cooling system of claim 1, wherein the heat exchange fluid comprises water, gas, a fluid, or mineral oil.

12. The uninterruptible cooling system of claim 1, wherein the heat exchanger is configured to reduce a temperature of the heat exchange fluid from a temperature greater than the phase change threshold to a temperature less than the phase change threshold.

13. The uninterruptible cooling system of claim 1, wherein the casing is a rectangular prism.

14. A method for removing heat from a heat exchange fluid using a heat transfer compound, comprising:
circulating the heat exchange fluid through a first container containing a heat generating electronic component, through a second container containing a heat exchanger configured to absorb heat transferred from the heat generating electronic component to the heat exchange fluid, and through an Uninterruptible Cooling Supply (UCS);
rejecting heat from the heat transfer compound into the heat exchange fluid until the heat transfer compound reaches a solid state when an operating temperature of the heat exchange fluid downstream of the heat exchanger is at or below a phase change threshold, and
absorbing heat from the heat exchange fluid using the heat transfer compound when the operating temperature of the heat exchange fluid is above the phase change threshold.

15. The method of claim 14, further comprising continuing to circulate the heat exchange fluid to cool the heat generating electronic component.

16. The method of claim 14, further comprising maintaining a temperature of the heat generating electronic component at a constant temperature for a period of time that encompasses a phase change of the heat transfer compound.

17. The method of claim 14, further comprising transitioning the heat transfer compound from a solid to a liquid state when an elevated operating temperature is greater than an operating temperature of the heat exchange fluid and less than the temperature of the heat generating electronic component.

18. The method of claim 14, further comprising reducing a temperature of the heat exchange fluid from a temperature greater than the phase change threshold to a temperature less than the phase change threshold in the second container.

19. The method of claim 14, further comprising selecting a radiator size and a casing size to correspond to a heat load of the heat generating electronic component.

20. The method of claim 14, further comprising reducing a temperature of the heat exchange fluid from a temperature greater than the phase change threshold to a temperature less than the phase change threshold with the heat exchanger.
